(19) United States
(12) Patent Application Publication
(10) Pub. No.: US 2024/0155953 A1
(43) Pub. Date: May 9, 2024

(54) SEMICONDUCTOR DEVICE AND METHOD FOR FABRICATING THE SAME

(71) Applicants: SK hynix Inc., Gyeonggi-do (KR); Kioxia Corporation, Tokyo (JP)

(72) Inventors: Cha Deok DONG, Gyeonggi-do (KR); Guk Cheon KIM, Gyeonggi-do (KR); Bo Kyung JUNG, Gyeonggi-do (KR); Keo Rock CHOI, Gyeonggi-do (KR); Kenichi YOSHINO, Tokyo (JP); Kazuya SAWADA, Tokyo (JP); Naoki AKIYAMA, Tokyo (JP); Takuya SHIMANO, Tokyo (JP)

(21) Appl. No.: 18/331,186

(22) Filed: Jun. 8, 2023

(30) Foreign Application Priority Data
Nov. 8, 2022 (KR) 10-2022-0147652

(51) Int. Cl. H10N 70/00; H10B 63/00

(52) U.S. Cl. CPC H10N 70/066; H10B 63/84; H10N 70/063; H10N 70/826; H10N 70/841

(57) ABSTRACT

A semiconductor device may include a first pattern including any one of a selector layer or a variable resistance layer and a middle electrode layer disposed over any one of the selector layer or the variable resistance layer; and a second pattern disposed over the first pattern and including the other one of the selector layer or the variable resistance layer, wherein a width of the second pattern may be the same as or greater than a width of the first pattern.

### CROSS-REFERENCE TO RELATED APPLICATIONS

The present application claims priority to Korean Patent Application No. 10-2022-0147652, filed on Nov. 8, 2022, which is incorporated herein by reference in its entirety.

### BACKGROUND

### 1. Field

Various embodiments of the present invention relate to memory circuits or devices and their applications in electronic devices or systems.

### 2. Description of the Related Art

The recent trend toward miniaturization, low power consumption, high performance, and multi-functionality in the electrical and electronics industry has compelled the semiconductor manufacturers to focus on high-performance, high capacity semiconductor devices.

Examples of such high-performance, high capacity semiconductor devices include memory devices that can store data by switching between different resistance states according to an applied voltage or current. The semiconductor devices may include an RRAM (resistive random access memory), a PRAM (phase change random access memory), an FRAM (ferroelectric random access memory), an MRAM (magnetic random access memory), and an electronic fuse (E-fuse).

### SUMMARY

Various embodiments of the present invention include memory circuits or devices and their applications in semiconductor devices or systems and various embodiments of a semiconductor device that can improve the performance of a semiconductor device.

In accordance an embodiment, a semiconductor device may include: a first pattern including any one of a selector layer or a variable resistance layer and a middle electrode layer disposed over any one of the selector layer or the variable resistance layer; and a second pattern disposed over the first pattern and including the other one of the selector layer or the variable resistance layer, wherein a width of the second pattern may be the same as or greater than a width of the first pattern.

In accordance with an embodiment, a method for fabricating a semiconductor device may include: forming a first material layer for forming any one of a selector layer or a variable resistance layer over a substrate; forming a second material layer for forming a middle electrode layer over the first material layer; etching the second material layer and the first material layer through a first patterning process using a first hard mask pattern to form a first pattern including any one of the selector layer or the variable resistance layer and the middle electrode layer; forming a third material layer for forming the other one of the selector layer or the variable resistance layer over the first pattern; and etching the third material layer through a second patterning process using a second hard mask pattern to form a second pattern including the other one of the selector layer or the variable resistance layer.

In accordance with an embodiment, a method for fabricating a semiconductor device may include: forming a first pattern including any one of a selector layer or a variable resistance layer and a middle electrode layer disposed over any one of the selector layer or the variable resistance layer over a substrate; and forming a second pattern including the other one of the selector layer or the variable resistance layer over the first pattern, wherein a width of the second pattern may be the same as or greater than a width of the first pattern.

### BRIEF DESCRIPTION OF THE DRAWINGS

FIGS. 1A and 1B illustrate a semiconductor device in accordance an embodiment of the present invention.

FIG. 2 is a cross-sectional view illustrating a magnetic tunnel junction (MTJ) structure in accordance an embodiment of the present invention.

FIGS. 3A to 3J are cross-sectional views illustrating a semiconductor device and a method for forming the same in accordance an embodiment of the present invention.

FIG. 4 is a cross-sectional view illustrating a semiconductor device in accordance with an embodiment of the present invention.

FIGS. 5A to 5D are cross-sectional views illustrating a semiconductor device and a method for forming the same in accordance with an embodiment of the present invention.

FIGS. 6 to 11 are cross-sectional views illustrating semiconductor devices in accordance with an embodiment of the present invention.

### DETAILED DESCRIPTION

Various embodiments of the present invention may be described herein with reference to cross-sectional views, plane views and block diagrams, which are simplified schematic views of the semiconductor device. It is noted that the structures of the drawings may be modified by fabricating techniques and/or tolerances. The present invention is not limited to the described embodiments and the specific structures shown in the drawings, but may include other embodiments, or modifications of the described embodiments including any changes in the structures that may be produced according to requirements of the fabricating process. Accordingly, the regions illustrated in the drawings have schematic attributes, and the shapes of the regions illustrated in the drawings are intended to illustrate specific structures of regions of the elements, and are not intended to limit the scope of the invention.

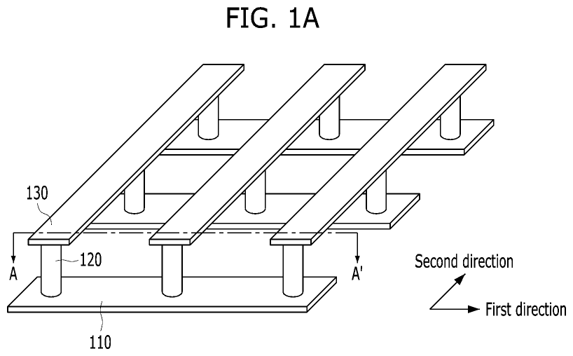

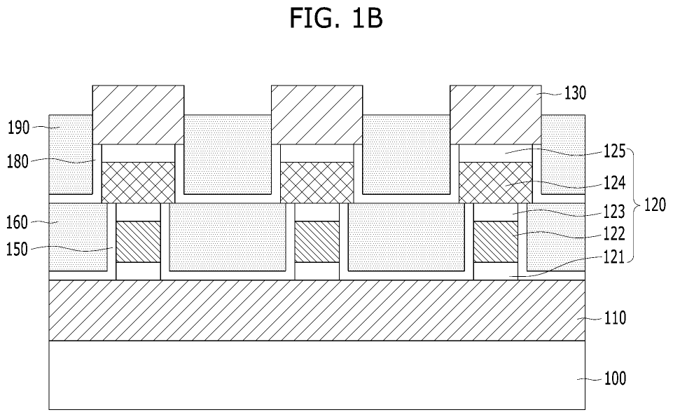

FIGS. 1A and 1B illustrate a semiconductor device in accordance an embodiment of the present invention. FIG. 1A is a perspective view, and FIG. 1B is a cross-sectional view taken along line A-A′ of FIG. 1A.

Referring to FIGS. 1A and 1B, the semiconductor device may include a cross-point structure including a substrate 100, first conductive lines 110 formed over the substrate 100 and extending in a first direction, second conductive lines 130 formed over the first conductive lines 110 to be spaced apart from the first conductive lines 110 and extending in a second direction crossing the first direction, and memory cells 120 disposed at intersections of the first conductive lines 110 and the second conductive lines 130 between the first conductive lines 110 and the second conductive lines 130. In this patent document, the conductive lines can indicate conductive structures that electrically connect two or more circuit elements in the semiconductor memory. In some embodiments, the conductive lines include word lines that are used to control access to memory cells in the memory device and bit lines that are used to read out information stored in the memory cells. In some embodiments, the conductive lines include interconnects that carry signals between different circuit elements in the semiconductor memory.

The substrate 100 may include a semiconductor material such as silicon. A required lower structure (not shown) may be formed in the substrate 100. For example, the substrate 100 may include a driving circuit (not shown) electrically connected to the first conductive lines 110 and/or the second conductive lines 130 to control operations of the memory cells 120.

The first conductive lines 110 and the second conductive lines 130 may be connected to a lower end and an upper end of the memory cell 120, respectively, and may provide a voltage or a current to the memory cell 120 to drive the memory cell 120. When the first conductive lines 110 function as a word line, the second conductive lines 130 may function as a bit line. Conversely, when the first conductive lines 110 function as a bit line, the second conductive lines 130 may function as a word line. The first conductive lines 110 and the second conductive lines 130 may include a single-layered structure or a multi-layered structure including one or more of various conductive materials. Examples of the conductive materials may include a metal, a metal nitride, or a conductive carbon material, or a combination thereof, but are not limited thereto. For example, the first conductive lines 110 and the second conductive lines 130 may include tungsten (W), titanium (Ti), tantalum (Ta), platinum (Pt), aluminum (Al), copper (Cu), zinc (Zn), nickel (Ni), cobalt (Co), lead (Pb), tungsten nitride (WN), tungsten silicide (WSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), carbon (C), silicon carbide (SiC), or silicon carbon nitride (SiCN), or a combination thereof.

The memory cell 120 may be arranged in a matrix having rows and columns along the first direction and the second direction so as to overlap the intersection regions between the first conductive lines 110 and the second conductive lines 130. In an embodiment, each of the memory cells 120 may have a size that is substantially equal to or smaller than that of the intersection region between each corresponding pair of the first conductive lines 110 and the second conductive lines 130. In another embodiment, each of the memory cells 120 may have a size that is larger than that of the intersection region between each corresponding pair of the first conductive lines 110 and the second conductive lines 130.

In the embodiment, the memory cell 120 has a cylinder shape. However, the shape of the memory cell 120 is not limited thereto. For example, the memory cell may have a square pillar shape.

Spaces between the first conductive lines 110, the second conductive lines 130 and the memory cell 120 may be filled with a first gap-fill layer 160 and a second gap-fill layer 190.

The first gap-fill layer 160 and the second gap-fill layer 190 may include an insulating material. The insulating material may include an oxide, or a nitride, or a combination thereof. For example, the first gap-fill layer 160 and the second gap-fill layer 190 may include SiO₂, SiN₄, SiOCN, or SiON or a combination thereof.

The first gap-fill layer 160 and the second gap-fill layer 190 may include the same material as each other or different materials from each other.

The memory cell 120 may include a stacked structure including a lower electrode layer 121, a selector layer 122, a middle electrode layer 123, a variable resistance layer 124 and an upper electrode 125.

The lower electrode layer 121 may be interposed between the first conductive line 110 and the selector layer 122 and disposed at a lowermost portion of each of the memory cells 120. The lower electrode layer 121 may function as a circuit node that carries a current or applies a voltage between one of the first conductive lines 110 and the remaining portion (e.g., the elements 122, 123, 124 and 125) of each of the memory cells 120. The middle electrode layer 123 may be interposed between the selector layer 122 and the variable resistance layer 124. The middle electrode layer 123 may electrically connect the selector layer 122 and the variable resistance layer 124 to each other while physically isolating or separating the selector layer 122 and the variable resistance layer 124 from each other. The upper electrode layer 125 may be disposed at an uppermost portion of the memory cell 120 and function as a transmission path of electrical signals such as a voltage or a current between a material layer in the memory cell 120 and one of the second conductive lines 130.

The lower electrode layer 121, the middle electrode layer 123 and the upper electrode layer 125 may include a single-layered structure or a multi-layered structure including various conductive materials such as a metal, a metal nitride, a conductive carbon material, or a combination thereof, respectively. For example, the lower electrode layer 121, the middle electrode layer 123 and the upper electrode layer 125 may include tungsten (W), titanium (Ti), tantalum (Ta), platinum (Pt), aluminum (Al), copper (Cu), zinc (Zn), nickel (Ni), cobalt (Co), lead (Pb), tungsten nitride (WN), tungsten silicide (WSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), carbon (C), silicon carbide (SiC), or silicon carbon nitride (SiCN), or a combination thereof.

The lower electrode layer 121, the middle electrode layer 123 and the upper electrode layer 125 may include the same material as each other or different materials from each other.

The lower electrode layer 121, the middle electrode layer 123 and the upper electrode layer 125 may have the same thickness as each other or different thicknesses from each other.

At least one of the lower electrode layer 121, the middle electrode layer 123, and the upper electrode layer 125 may be omitted. When the lower electrode layer 121 is omitted, the first conductive line 110 may perform a function as the lower electrode layer 121. When the upper electrode layer 125 is omitted, the second conductive line 130 may perform a function as the upper electrode layer 125.

The selector layer 122 may serve to control access to the variable resistance layer 124 and prevent a current leakage between the memory cells 120 sharing the first line 110 or the second line 130. To this end, the selector layer 122 may have a threshold switching characteristic that blocks or substantially limits a current when a magnitude of an applied voltage is less than a predetermined threshold value and allows the current to increase rapidly when the magnitude of the applied voltage is equal to or greater than the predetermined threshold value. This threshold value may be referred to as a threshold voltage, and the selector layer 122 may be controlled to be in either a turned-on or “on” state to be electrically conductive or a turned-off or “off” state to be electrically less-conductive than the “on” state or electrically non-conductive depending on whether the applied voltage is above or below the threshold voltage. Thus, the selector layer 122 exhibits different electrically conductive states to provide a switching operation to switch between the different electrically conductive states by controlling the applied voltage relative to the threshold voltage. The selector layer 122 may include Metal Insulator Transition (MIT) material such as NbO₂, TiO₂, VO₂, WO₂, or others, Mixed Ion-Electron Conducting (MIEC) material such as ZrO₂(Y₂O₃), Bi₂O₃—BaO, (La₂O₃)ₓ(CeO₂)₁₋ₓ, or others, Ovonic Threshold Switching (OTS) material including chalcogenide material such as Ge₂Sb₂Te₅, As₂Te₃, As₂, As₂Se₃, or others, or a tunneling insulating material such as silicon oxide, silicon nitride, a metal oxide, or others. A thickness of the tunneling insulating layer is sufficiently small to allow tunneling of electrons through the tunneling insulating layer under a given voltage or a given current. The selector layer 122 may include a single-layered structure or a multi-layered structure.

In some embodiments, the selector layer 122 may perform a threshold switching operation through a doped region formed in a material layer for the selector layer 122. Thus, a size of the threshold switching operation region may be controlled by a distribution area of the dopants. The dopants may form trap sites for charge carriers in the material layer for the selector layer 122. The trap sites may capture the charge carriers moving in the selector layer 122 based on an external voltage applied to the selector layer 122. The trap sites thereby provide a threshold switching characteristic and are used to perform a threshold switching operation.

In some embodiments, the selector layer 122 may include a dielectric material having incorporated dopants. The selector layer 122 may include an oxide with dopants, a nitride with dopants, or an oxynitride with dopants, or a combination thereof such as silicon oxide, titanium oxide, aluminum oxide, tungsten oxide, hafnium oxide, tantalum oxide, niobium oxide, silicon nitride, titanium nitride, aluminum nitride, tungsten nitride, hafnium nitride, tantalum nitride, niobium nitride, silicon oxynitride, titanium oxynitride, aluminum oxynitride, tungsten oxynitride, hafnium oxynitride, tantalum oxynitride, or niobium oxynitride, or a combination thereof. The dopants doped into the selector layer 122 may include an n-type dopant or a p-type dopant and be incorporated for example, by ion implantation process. Examples of the dopants may include one or more of boron (B), nitrogen (N), carbon (C), phosphorous (P), arsenic (As), aluminum (Al), silicon (Si) or germanium (Ge). For example, the selector layer 122 may include As-doped silicon oxide or Ge-doped silicon oxide.

The variable resistance layer 124 may be used to store data by switching between different resistance states according to an applied voltage or current. The variable resistance layer 124 may have a single-layered structure or a multi-layered structure including at least one of materials having a variable resistance characteristic used for an RRAM, a PRAM, an MRAM, an FRAM, and others. For example, the variable resistance layer 124 may include a metal oxide such as a transition metal oxide or a perovskite-based oxide, a phase change material such as a chalcogenide-based material, a ferromagnetic material, a ferroelectric material, or others. The variable resistance layer 124 may have a single-layered structure or a multi-layered structure exhibiting a variable resistance characteristic. However, the embodiments are not limited thereto, and the memory cell 120 may include other memory layers capable of storing data in various ways instead of the variable resistance layer 124.

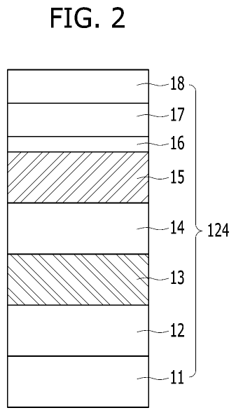

In some embodiments, the variable resistance layer 124 may include a magnetic tunnel junction (MTJ) structure. This will be explained with reference to FIG. 2.

FIG. 2 illustrates a Magnetic Tunnel Junction (MTJ) structure included in the variable resistance layer 124.

The variable resistance layer 124 may include an MTJ structure including a free layer 13 having a variable magnetization direction, a pinned layer 15 having a pinned magnetization direction and a tunnel barrier layer 14 interposed between the free layer 13 and the pinned layer 15.

The free layer 13 may have one of different magnetization directions or one of different spin directions of electrons to switch the polarity of the free layer 13 in the MTJ structure, resulting in changes in resistance value. In some implementations, the polarity of the free layer 13 is changed or flipped upon application of a voltage or current signal (e.g., a driving current above a certain threshold) to the MTJ structure. With the polarity changes of the free layer 13, the free layer 13 and the pinned layer 15 have different magnetization directions or different spin directions of electron, which allows the variable resistance layer 124 to store different data or represent different data bits. The free layer 13 may also be referred as a storage layer. The magnetization direction of the free layer 13 may be substantially perpendicular to a surface of the free layer 13, the tunnel barrier layer 14 and the pinned layer 15. In other words, the magnetization direction of the free layer 13 may be substantially parallel to stacking directions of the free layer 13, the tunnel barrier layer 14 and the pinned layer 15. Therefore, the magnetization direction of the free layer 13 may be changed between a downward direction and an upward direction. The change in the magnetization direction of the free layer 13 may be induced by a spin transfer torque generated by an applied current or voltage.

The free layer 13 may have a single-layered structure or a multi-layered structure including a ferromagnetic material. For example, the free layer 13 may include an alloy based on Fe, Ni or Co, for example, an Fe—Pt alloy, an Fe—Pd alloy, a Co—Pd alloy, a Co—Pt alloy, a Co—Fe alloy, an Fe—Ni—Pt alloy, a Co—Fe—Pt alloy, a Co—Ni—Pt alloy, or a Co—Fe—B alloy, or others, or may include a stack of metals, such as Co/Pt, or Co/Pd, or others.

The tunnel barrier layer 14 may allow the tunneling of electrons in both data reading and data writing operations. In a write operation for storing new data, a high write current may be directed through the tunnel barrier layer 14 to change the magnetization direction of the free layer 13 and thus to change the resistance state of the MTJ for writing a new data bit. In a reading operation, a low reading current may be directed through the tunnel barrier layer 14 without changing the magnetization direction of the free layer 13 to measure the existing resistance state of the MTJ under the existing magnetization direction of the free layer 13 to read the stored data bit in the MTJ. The tunnel barrier layer 14 may include a dielectric oxide such as MgO, CaO, SrO, TiO, VO, or NbO or others.

The pinned layer 15 may have a pinned magnetization direction, which remains unchanged while the magnetization direction of the free layer 13 changes. The pinned layer 15 may be referred to as a reference layer. In some implementations, the magnetization direction of the pinned layer 15 may be pinned in a downward direction. In some implementations, the magnetization direction of the pinned layer 15 may be pinned in an upward direction.

The pinned layer 15 may have a single-layered structure or a multi-layered structure including a ferromagnetic material. For example, the pinned layer 15 may include an alloy based on Fe, Ni or Co, for example, an Fe—Pt alloy, an Fe—Pd alloy, a Co—Pd alloy, a Co—Pt alloy, a Co—Fe alloy, an Fe—Ni—Pt alloy, a Co—Fe—Pt alloy, a Co—Ni—Pt alloy, or a Co—Fe—B alloy, or may include a stack of metals, such as Co/Pt, or Co/Pd or others.

If a voltage or current is applied to the variable resistance layer 124, the magnetization direction of the free layer 13 may be changed by spin transfer torque. In some implementations, when the magnetization directions of the free layer 13 and the pinned layer 15 are parallel to each other, the variable resistance layer 124 may be in a low resistance state, and this may indicate digital data bit “0.” Conversely, when the magnetization directions of the free layer 13 and the pinned layer 15 are anti-parallel to each other, the variable resistance layer 124 may be in a high resistance state, and this may indicate a digital data bit “1.” In some implementations, the variable resistance layer 124 can be configured to store data bit ‘1’ when the magnetization directions of the free layer 13 and the pinned layer 15 are parallel to each other and to store data bit ‘0’ when the magnetization directions of the free layer 13 and the pinned layer 15 are anti-parallel to each other.

In some implementations, the variable resistance layer 124 may further include one or more layers performing various functions to improve a characteristic of the MTJ structure. For example, the variable resistance layer 124 may further include at least one of a buffer layer 11, an under layer 12, a spacer layer 16, a magnetic correction layer 17 and a capping layer 18.

The under layer 12 may be disposed under the free layer 13 and serve to improve perpendicular magnetic crystalline anisotropy of the free layer 13. The under layer 12 may have a single-layered structure or a multi-layered structure including a metal, a metal alloy, a metal nitride, or a metal oxide, or a combination thereof.

The buffer layer 11 may be disposed below the under layer 12 to facilitate crystal growth of the under layer 12, thus improving perpendicular magnetic crystalline anisotropy of the free layer 13. The buffer layer 11 may have a single-layered structure or a multi-layered structure including a metal, a metal alloy, a metal nitride, or a metal oxide, or a combination thereof. Moreover, the buffer layer 11 may be formed of or include a material having a good compatibility with a bottom electrode (not shown) in order to resolve the lattice constant mismatch between the bottom electrode and the under layer 12. For example, the buffer layer 11 may include tantalum (Ta).

The spacer layer 16 may be interposed between the magnetic correction layer 17 and the pinned layer 15 and function as a buffer between the magnetic correction layer 17 and the pinned layer 15. The spacer layer 16 may serve to improve characteristics of the magnetic correction layer 17. The spacer layer 16 may include a noble metal such as ruthenium (Ru).

The magnetic correction layer 17 may serve to offset the effect of the stray magnetic field produced by the pinned layer 15. In this case, the effect of the stray magnetic field of the pinned layer 15 can decrease, and thus a biased magnetic field in the free layer 13 can decrease. The magnetic correction layer 17 may have a magnetization direction anti-parallel to the magnetization direction of the pinned layer 15. In the implementation, when the pinned layer 15 has a downward magnetization direction, the magnetic correction layer 17 may have an upward magnetization direction. Conversely, when the pinned layer 15 has an upward magnetization direction, the magnetic correction layer 17 may have a downward magnetization direction. The magnetic correction layer 17 may be exchange coupled with the pinned layer 15 via the spacer layer 16 to form a synthetic anti-ferromagnet (SAF) structure. The magnetic correction layer 17 may have a single-layered structure or a multi-layered structure including a ferromagnetic material.

In this implementation, the magnetic correction layer 17 is located above the pinned layer 15, but the magnetic correction layer 17 may disposed at a different location. For example, the magnetic correction layer 17 may be located above, below, or next to the MTJ structure while the magnetic correction layer 17 is patterned separately from the MTJ structure.

The capping layer 18 may serve to protect the variable resistance layer 124 and/or function as a hard mask for patterning the variable resistance layer 124. In some implementations, the capping layer 18 may include various conductive materials such as a metal. In some implementations, the capping layer 18 may include a metallic material having almost none or a small number of pin holes and high resistance to wet and/or dry etching. In some implementations, the capping layer 18 may include a metal, a nitride, or an oxide, or a combination thereof. For example, the capping layer 18 may include a noble metal such as ruthenium (Ru).

The capping layer 18 may have a single-layered structure or a multi-layered structure. In some implementations, the capping layer 18 may have a multilayer structure including an oxide, or a metal, or a combination thereof. For example, the capping layer 18 may have a multilayer structure of an oxide layer, a first metal layer and a second metal layer.

A material layer (not shown) for resolving the lattice structure differences and the lattice constant mismatch between the pinned layer 15 and the magnetic correction layer 17 may be interposed between the pinned layer 15 and the magnetic correction layer 17. For example, this material layer may be amorphous and may include a metal a metal nitride, or metal oxide.

In some implementations, each of the memory cell 120 includes the lower electrode layer 121, the selector layer 122, the middle electrode layer 123, the variable resistance layer 124 and the upper electrode layer 125 which are sequentially stacked. However, the memory cells 120 may have different structures. In some implementations, the selector layer 122 and the variable resistance layer 124 may be stacked in a different order. For example, the selector layer 122 and the variable resistance layer 124 may be stacked in a reverse order with respect to the orientation shown in FIG. 1B, such that the selector layer 122 may be disposed over the variable resistance layer 124. In some implementations, at least one of the lower electrode layer 121, the middle electrode layer 123, and the upper electrode layer 125 may be omitted. In some implementations, in addition to the layers 121 to 125 shown in FIG. 1B, the memory cells 120 may further include one or more layers (not shown) for enhancing characteristics of the memory cells 120 or improving fabricating processes.

In some implementations, neighboring memory cells of the plurality of memory cells 120 may be spaced apart from each other at a predetermined interval, and trenches may be present between the plurality of memory cells 120. A trench between neighboring memory cells 120 may have a height to width ratio (i.e., an aspect ratio) in a range from 1:1 to 40:1, from 10:1 to 40:1, from 10:1 to 20:1, from 5:1 to 10:1, from 10:1 to 15:1, from 1:1 to 25:1, from 1:1 to 30:1, from 1:1 to 35:1, or from 1:1 to 45:1.

In some implementations, the trench may have sidewalls that are substantially perpendicular to an upper surface of the substrate 100. In some implementations, neighboring trenches may be spaced apart from each other by an equal or similar distance.

To form a high-density cross-point array, the variable resistance layer 124 and the selector layer 122 have been usually formed on an upper portion and a lower portion of the same element. When the variable resistance layer 124 includes an MTJ structure, the variable resistance layer 124 includes various layers made of different materials and is combined with the selector layer 122 and electrode layers 121, 123 and 125 including a metal. Therefore, it is very difficult to etch the memory cell 120. In order to completely etch the memory cell 120 from top to bottom and prevent loss of the variable resistance layer 124, a very complex process in which an ion beam etch (IBE) process is combined with a reactive ion etch (RIE) process should be used. At this time, as the width of spaces between the memory cells 120 decreases, an etch burden for the memory cell 120 increases and a thick hard mask pattern is required. Further, it becomes more difficult to etch at a desired angle or apply an appropriate etchant. Also, during etching the memory cell 120, redeposition of the metal material included in the electrode layers 121, 123 and 125 is inevitably accompanied and a short may occur in an area to be insulated. Moreover, as sidewall slopes are formed in some layers, the lower electrode layer 121 disposed at the lowermost portion of the memory cell 120 may not be completely separated. As such, significant obstacles may occur in patterning the memory cell 120.

In recognition of the above problems and for overcoming these problems, in embodiments of the present invention, a lower pattern (first pattern) and an upper pattern (second pattern) included in the memory cell 120 may be formed by a separate patterning process. In this embodiment, the lower pattern (first pattern) of the memory cell 120 may include the selector layer 122, and the upper pattern (second pattern) may include the variable resistance layer 124. For example, the lower pattern including the lower electrode layer 121, the selector layer 122 and the middle electrode layer 123 may be formed by a first patterning process, and then the upper pattern including the variable resistance layer 124 and the upper electrode layer 125 may be formed by a second patterning process. Compared to the case of simultaneously forming the lower pattern and the upper pattern by one patterning process, when the lower pattern and the upper pattern are sequentially formed by a separate patterning process, an etch burden may be reduced and etch efficiency may be improved because the height of the structure to be etched in each patterning process is decreased. Moreover, since the thickness of the hard mask pattern can be decreased, it is possible to further improve a vertical profile of the memory cell 120 by utilizing a tilted ion beam etch process for patterning the upper pattern including the variable resistance layer 124 having a multilayer composite structure. Further, the lower electrode layer 121 can be easily separated and a sufficiently vertical structure can be secured, thereby reducing etch damage to sidewalls of the selector layer 122. In addition, by planarizing the middle electrode layer 123 before deposition of material layers for forming the upper pattern, it has an advantageous effect on the formation of the variable resistance layer 124 including the MTJ where deposition and crystal growth according to the crystal orientation are important. As a result, characteristics of the memory cell 120 can be further improved.

A pattern including the selector layer 122 may be also represented as an S-pattern and a pattern including the variable resistance layer 124 may be also represented as an M-pattern. In this embodiment, the S-pattern is the lower pattern and the M-pattern is the upper pattern. However, in another embodiment, the relative positions of the selector layer 122 and the variable resistance layer 124 may be reversed. In this case, the S-pattern may be the upper pattern and the M-pattern may be the lower pattern.

In some embodiments, a width of the upper pattern may be the same as a width of the lower pattern or greater than the width of the lower pattern. In the embodiment shown in FIG. 1b, the width of the M-pattern (upper pattern) may be greater than the width of the S-pattern (lower pattern). That is, a width of the variable resistance layer 124 disposed at a lower portion of the M-pattern may be greater than a width of the middle electrode layer 123 disposed at an upper portion of the S-pattern. Contrary to this embodiment, according to the comparative embodiment, since the width of the upper pattern is smaller than the width of the lower pattern, the middle electrode layer 123 is exposed during over-etching for separating the variable resistance layer 124, resulting in inevitable loss of the middle electrode layer 123. The etched material of the middle electrode layer 123 is redeposited on sidewalls of the variable resistance layer 124 to cause a shunt phenomenon in which a current freely flows inside the variable resistance layer 124. In this embodiment, in order to overcome these problems, the width of the upper pattern is greater than the width of the lower pattern. Therefore, it is possible to prevent the middle electrode layer 123 from being etched and lost during over-etching for M-pattern separation. Accordingly, shunt failure caused by redeposition of the material of the middle electrode layer 123 can be effectively controlled.

In this embodiment, the width of the upper pattern is greater than the width of the lower pattern. In another embodiment, the width of the upper pattern is the same as the width of the lower pattern. Even when the width of the upper pattern is the same as the width of the lower pattern, the same effect as described above can be obtained.

In this embodiment, the semiconductor device may further include a first capping layer 150 and a second capping layer 180.

The first capping layer 150 may serve to protect the S-pattern (lower pattern) including the lower electrode layer 121, the selector layer 122 and the middle electrode layer 123 from external influences. The first capping layer 150 may be formed over the first conductive line 110 and on sides of the lower electrode layer 121, the selector layer 122 and the middle electrode layer 123. The first capping layer 150 may cover entirely the sides of the lower electrode layer 121, the selector layer 122 and the middle electrode layer 123.

The first capping layer 150 may be formed to have a predetermined minimum thickness for preventing damage to the selector layer 122 during the formation of the M-pattern including the variable resistance layer 124 and the upper electrode layer 125.

The first capping layer 150 may include an insulating material, or Poly-Si, or a combination thereof and have a single-layered or a multi-layered structure. The insulating material may include an oxide, or a nitride, or a combination thereof. For example, the first capping layer 150 may include SiO₂, SiN₄, SiOCN, SiON, or poly-Si, or a combination thereof.

In an embodiment, the first capping layer 150 and the first gap-fill layer 160 may have the same material as each other.

In an embodiment, the first capping layer 150 and the first gap-fill layer 160 may have different materials from each other. In this case, these materials may be combined to minimize or reduce a difference in etching selectivity.

After forming the S-pattern, the first capping layer 150 and the first gap-fill layer 160, a planarization process may be performed to secure surface morphology of the upper part of the S-pattern for crystal growth when subsequently forming the M-pattern. Considering planarization, the first capping layer 150 and the first gap-fill layer 160 may include the same material as each other, or different materials from each other with a small or minimum difference in etching selectivity.

The second capping layer 180 may serve to protect the M-pattern including the variable resistance layer 124 and the upper electrode layer 125 from external influences and function as a stop barrier when forming the second conductive line 130 or an upper contact (not shown). In an embodiment, the second capping layer 180 may cover entirely the sides (also referred to as sidewalls) of the M-pattern (upper pattern) including the sides of the variable resistance layer 124 and the upper electrode layer 125.

The second capping layer 180 may have a predetermined minimum thickness for preventing damage to the variable resistance layer 124 during the formation of the second conductive line 130 or of an upper contact (not shown).

The second capping layer 180 may include an insulating material, or poly-Si (polycrystalline silicon), or a combination thereof and may have a single-layered or a multi-layered structure. The insulating material may include an oxide, or a nitride, or a combination thereof. For example, the second capping layer 180 may include SiO₂, SiN₄, SiOCN, SiON, or poly-Si, or a combination thereof.

The first capping layer 150 and the second capping layer 180 may be made of the same material as shown in the embodiment of FIG. 1B, however, they may also be made of different materials.

In an embodiment, the first capping layer 150, or the second capping layer 180, or both the first and the second capping layers 150 and 180 may include an air space formed in a void shape. It has been found that by using voids, interference between the memory cells 120 can be more effectively reduced or prevented. It has been further found that air spaces having void shapes may be readily formed by simply increasing the deposition rate. The increase of the deposition rate can be controlled by increasing one of a temperature, pressure, power or gas flow rate or any combination thereof. These methods for increasing the deposition rate are well known to those skilled in the art. Any of these methods may be used to create the air spaces in the first and second capping layers 150 and 180.

The first capping layer 150 and the second capping layer 180 may have the same thickness as shown in the embodiment of FIG. 1B, however, it is noted that in other embodiments the first capping layer 150 and the second capping layer 180 may have different thicknesses.

In an embodiment, the first capping layer 150 may have a greater thickness than that of the second capping layer 180.

Further, the first gap-fill layer 160 and the second gap-fill layer 190 may be made of the same material as shown in the embodiment of FIG. 1B, however, in other embodiments the first gap-fill layer 160 and the second gap-fill layer 190 may be made of different materials.

In some embodiments, the semiconductor device may include further layers in addition to the first conductive line 110, the memory cell 120 and the second conductive line 130. For example, a lower electrode contact may be further formed between the first conductive line 110 and the lower electrode layer 121 and an upper electrode contact may be further formed between the second conductive line 130 and the upper electrode layer 125.

Although one cross-point structure has been described, two or more cross-point structures may be stacked in a vertical direction perpendicular to a top surface of the substrate 100.

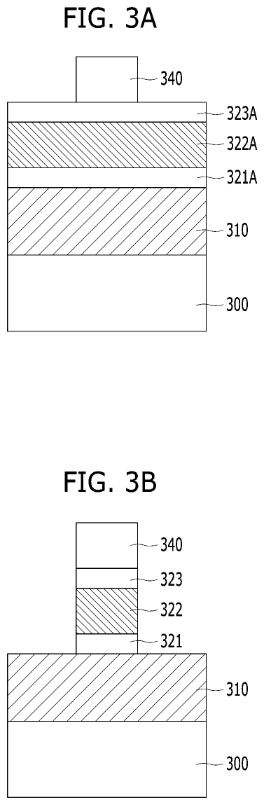

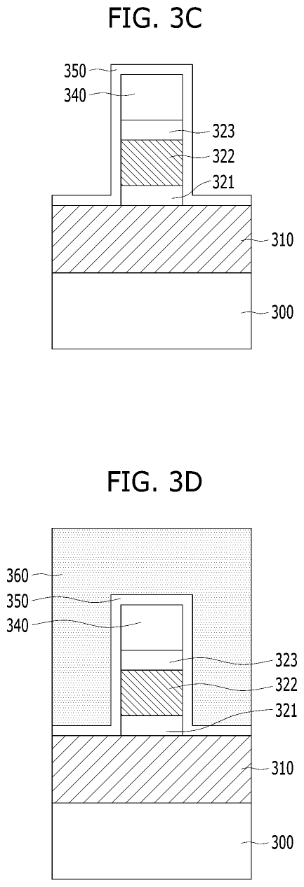

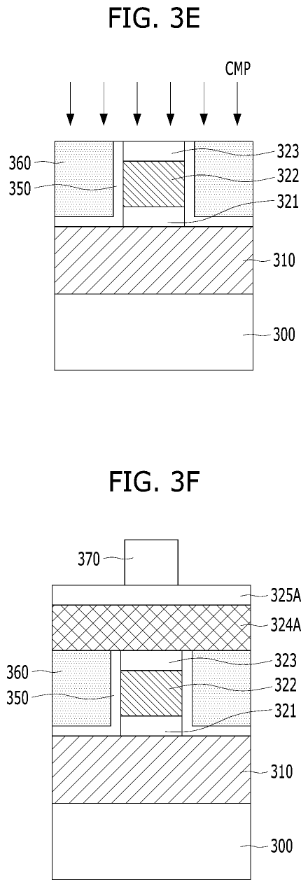

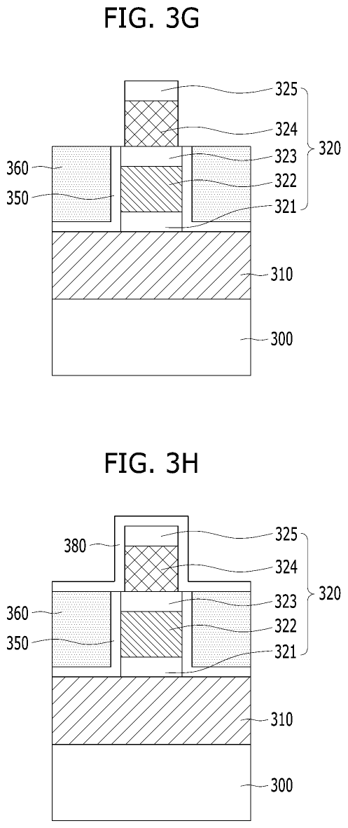

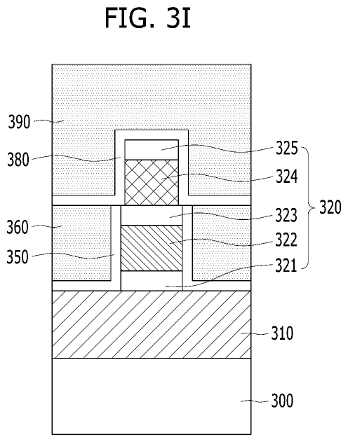

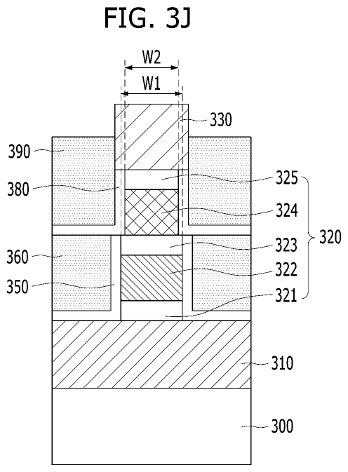

A method for fabricating a semiconductor device will be explained with reference to FIGS. 3A to 3J. Detailed description of contents similar to those explained with reference to FIGS. 1A, 1B and 2 will be omitted.

In the embodiment shown in FIGS. 3A to 3J, a memory cell 320 may include an upper pattern and a lower pattern. The upper pattern may be an upper portion of the memory cell 320 (see FIG. 3G) and may be an M-pattern including a variable resistance layer 324 and an upper electrode layer 325. The lower pattern forms a lower portion of the memory cell 320 and may be an S-pattern including a lower electrode layer 321, a selector layer 322 and a middle electrode layer 323.

Referring to FIG. 3A, first conductive lines 310 may be formed over a substrate 300 in which a predetermined structure is formed. For example, the first conductive lines 310 may be formed by forming a gap-fill layer (not shown) having a trench for forming the first conductive lines 310 over the substrate 300, depositing a conductive layer for forming the first conductive lines 310 in the trench, and etching the conductive layer using a mask pattern in a line shape extending in a first direction.

Then, a material layer 321A for forming a lower electrode layer, a material layer 322A for forming a selector layer and a material layer 323A for forming a middle electrode layer 323A may be formed over the first conductive lines 310.

Then, a first hard mask pattern 340 may be formed over the material layer 323A. The first hard mask pattern 340 may function as an etch barrier for forming the S-pattern. In this embodiment, the S-pattern may include the lower electrode layer 321, the selector layer 322 and the middle electrode layer 323. Therefore, the first hard mask pattern 340 may have a thickness smaller than that of a mask pattern used when a memory cell is patterned by a single patterning process.

The first hard mask pattern 340 may include an insulating material, or poly-Si, or a combination thereof and may have a single-layered or a multi-layered structure. The insulating material may include an oxide, or a nitride, or a combination thereof. For example, the first hard mask pattern 340 may include SiO₂, SiN₄, SiOCN, SiON, or poly-Si, or a combination thereof.

In an embodiment, the first hard mask pattern 340 may include the same material as a first capping layer 350 and a first gap-fill layer 360.

In an embodiment, the first hard mask pattern 340 may include different materials from the first capping layer 350 and the first gap-fill layer 360. In this case, these materials may be combined to reduce or minimize a difference in etching selectivity.

In a subsequent process, after forming the S-pattern, the first capping layer 350 and the first gap-fill layer 360, a planarization process may be performed to secure morphology of the upper part of the S-pattern for crystal growth when subsequently forming the M-pattern. Considering planarization, the first capping layer 350 and the first gap-fill layer 360 may include the same material as each other, or different materials from each other with a small or minimum difference in etching selectivity.

The first hard mask pattern 340 may be formed by forming a hard mask (not shown) over the material layer 323A, forming a photoresist pattern over the hard mask and etching the hard mask using the photoresist pattern as an etch barrier. Before forming the photoresist pattern, an antireflection film (not shown) may be further formed over the hard mask to prevent reflection during an exposure process.

Referring to FIG. 3B, a stacked structure in which a lower electrode layer 321, a selector layer 322, a middle electrode layer 323 and the first hard mask pattern 340 are sequentially stacked may be formed by etching the material layer 323A, the material layer 322A and the material layer 321A using the first hard mask pattern 340 as an etch barrier. In this etch process, since the height of the structure to be etched is reduced, it is possible to secure a sufficiently vertical structure, thereby minimizing etch damage to the sidewalls of the selector layer 322.

In this embodiment, the first hard mask pattern 340 remains in the etch process. In another embodiment, the first hard mask pattern 340 may be removed in the etch process.

Referring to FIG. 3C, the first capping layer 350 may be conformally formed over the structure of FIG. 3B. That is, the first capping layer 350 may cover a top surface of the first conductive lines 310, sidewalls of the lower electrode layer 321, the selector layer 322, the middle electrode layer 323 and the first hard mask pattern 340, and a top surface of the first hard mask pattern 340.

The first capping layer 350 include an insulating material, or poly-Si, or a combination thereof and may have a single-layered or a multi-layered structure. The insulating material may include an oxide, or a nitride, or a combination thereof. For example, the first capping layer 350 may include SiO₂, SiN₄, SiOCN, SiON, or poly-Si, or a combination thereof.

In an embodiment, the first capping layer 350 and the first hard mask pattern 340 may include the same material, or different materials with a small or minimum difference in etching selectivity.

In addition, in an embodiment, the first capping layer 350 may include an air space formed in a void shape. The air space in a void shape may be formed by increasing the deposition rate, for example, by increasing temperature, pressure, power or gas flow rate.

Referring to FIG. 3D, the first gap-fill layer 360 may cover the structure of FIG. 3C.

The first gap-fill layer 360, the first hard mask pattern 340 and the first capping layer 350 may include the same material as each other, or different materials from each other with a small or minimum difference in etching selectivity.

Referring to FIG. 3E, a planarization process such as a chemical mechanical planarization (CMP) process may be performed to expose the middle electrode layer 323. Through the planarization process, a surface of the middle electrode layer 323 may be formed to be flat and the first hard mask pattern 340 may be removed.

It has been found that when the middle electrode layer 323 has a large surface roughness, the orientation and growth of crystals of the layers included in the variable resistance layer 324 may be adversely affected, and the performance and yield of the variable resistance layer 324 are decreased. Accordingly, the present invention method employs the planarization process of FIG. 3E, to ensure that the surface morphology of the middle electrode layer 323 is sufficiently smooth (also referred to as flat) to become suitable for the crystal growth.

After performing the planarization process, formation of the S-pattern is completed. The S-pattern includes the lower electrode layer 321, the selector layer 322 and the middle electrode layer 323 sequentially stacked over the first conductive lines 310.

As such, in this embodiment, since the S-pattern is formed by a separate patterning process before forming the variable resistance layer 324, the surface roughness of the S-pattern can be minimized. That is, it is possible to form the surface of the middle electrode layer 323 to be flat. Accordingly, the crystal growth of the variable resistance layer 324 formed over the middle electrode layer 323 can be improved, thereby effectively increasing the performance and yield of the variable resistance layer 324.

Referring to FIG. 3F, a material layer 324A for forming a variable resistance layer, a material layer 325A for forming an electrode layer and a second hard mask pattern 370 may be sequentially formed over the middle electrode layer 323.

The second hard mask pattern 370 may be served as an etch barrier for forming the M-pattern. In this embodiment, the M-pattern may include the middle electrode layer 324 and an upper electrode layer 325. The second hard mask pattern 370 may have a smaller thickness than that of a hard mask pattern used when the memory cell 320 is patterned by a single patterning process.

The second hard mask pattern 370 and the first hard mask pattern 340 may include the same material or different materials.

Referring to FIG. 3G, the M-pattern in which the variable resistance layer 324 and the upper electrode layer 325 are sequentially stacked may be formed over the S-pattern by etching the material layer 325A and the material layer 324A using the second hard mask pattern 370 as an etch barrier. Since the second hard mask pattern 370 used for forming the M-pattern has a small or minimum thickness (also referred to as a reduced or minimized thickness), it is possible to secure a further improved vertical profile of the memory cell 320 by utilizing a tilted ion beam etch process for patterning the M-pattern.

Through the process described above, the memory cell 320 in which the lower electrode layer 321, the selector layer 322, the middle electrode layer 323, the variable resistance layer 324 and the upper electrode layer 325 are sequentially stacked may be formed. In this embodiment, the second hard mask pattern 370 is removed in the etch process. In another process, the second hard mask pattern 370 may remain.

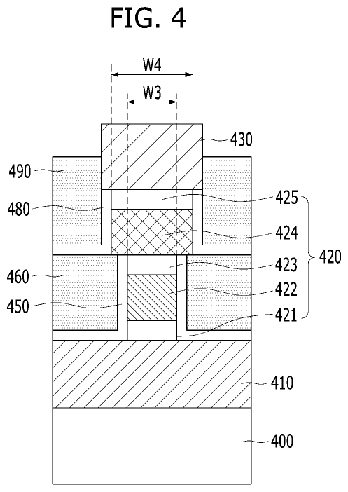

In the memory cell 320, the M-pattern is formed over the S-pattern. A width of the M-pattern may be smaller than that of the S-pattern. That is, a width of the variable resistance layer 324 may be smaller than that of the middle electrode layer 323. In another embodiment, the width of the M-pattern may be the same as or greater than the width of the S-pattern. This will be described with reference to FIG. 4.

Referring to FIG. 3H, a second capping layer 380 may be conformally formed over the structure of FIG. 3G. That is, the second capping layer 380 may cover a top surface of the first gap-fill layer 360, a top surface of the first capping layer 350, the sidewalls of the variable resistance layer 324 and the upper electrode layer 325, and a top surface of the upper electrode layer 325.

The second capping layer 380 may include an insulating material, or poly-Si, or a combination thereof and may have a single-layered or a multi-layered structure. The insulating material may include an oxide, or a nitride, or a combination thereof. For example, second capping layer 380 may include SiO₂, SiN₄, SiOCN, SiON, or poly-Si, or a combination thereof.

The second capping layer 380 and the first capping layer 350 may include the same material as each other or different materials from each other.

In an embodiment, the second capping layer 380 may include an air space formed in a void shape. The air space in a void shape may be formed by increasing the deposition rate, for example, by increasing temperature, pressure, power or gas flow rate.

Referring to FIG. 3I, a second gap-fill layer 390 may cover the structure of FIG. 3H.

The second gap-fill layer 390 and the first gap-fill layer 360 may include the same material as each other or different materials from each other.

Referring to FIG. 3J, second conductive lines 330 may be formed over the memory cell 320.

The second conductive lines 330 may be formed by forming a trench for forming the second conductive lines 330 over the memory cell 320, depositing a conductive layer for forming the second conductive lines 330 in the trench, and etching the conductive layer using a mask pattern in a line shape extending in a second direction.

Through the processes described above, the semiconductor device including the first conductive lines 310, the memory cell 320, the second conductive lines 330, the first capping layer 350, the first gap-fill layer 360, the second capping layer 380 and the second gap-fill layer 390 may be formed. The memory cell 320 may include the lower electrode layer 321, the selector layer 322, the middle electrode layer 323, the variable resistance layer 324 and the upper electrode layer 325 which are sequentially stacked.

In this embodiment, the S-pattern including the lower electrode layer 321, the selector layer 322 and the middle electrode layer 323 and the M-pattern including the variable resistance layer 324 and the upper electrode layer 325 may be formed by a separate patterning process. As such, it is possible to reduce an etch burden and increase etch efficiency, thereby allowing for securing a further improved vertical profile and minimizing damage to the sidewalls of the memory cell 320. Moreover, since the surface of the middle electrode layer 323 of the S-pattern is planarized before depositing the material layers for forming the M-pattern, it has an advantageous effect on the formation of the variable resistance layer 324 to improve characteristics of the memory cell 320. In this embodiment, the width W2 of the M-pattern is smaller than the width W1 of the S-pattern. In another embodiment, the width W2 of the M-pattern may be the same as or greater than the width W1 of the S-pattern. This will be described with reference to FIG. 4.

FIG. 4 is a cross-sectional view illustrating a semiconductor device in accordance with an embodiment of the present invention.

The embodiment shown in FIG. 4 is similar to the embodiment shown in FIGS. 3A to 3J except that a width W4 of an M-pattern including a variable resistance layer 424 and an upper electrode layer 425 is greater than a width W3 of an S-pattern including a lower electrode layer 421, a selector layer 422 and a middle electrode layer 423. Therefore, detailed description of contents similar to those explained with reference to FIGS. 3A to 3J will be omitted.

Referring to FIG. 4, the semiconductor device may include a substrate 400, a first conductive line 410, a memory cell 420, a second conductive line 430, a first capping layer 450, a first gap-fill layer 460, a second capping layer 480 and a second gap-fill layer 490. The memory cell 420 may include the lower electrode layer 421, the selector layer 422, the middle electrode layer 423, the variable resistance layer 424 and the upper electrode layer 425 which are sequentially stacked.

According to this embodiment, in addition to the advantageous effect obtained by forming the S-pattern and the M-pattern by the individual patterning process as described in the previous embodiment, an additional advantageous effect can be obtained by making the width W4 of the M-pattern disposed at an upper portion of the memory cell 420 larger than the width W3 of the S-pattern disposed at a lower portion of the memory cell 420.

First, in this embodiment, by forming the S-pattern and the M-pattern by a separate patterning process, it is possible to secure a further improved vertical profile of the memory cell 420 and to minimize damage to sidewalls of the memory cell 420. In addition, by planarizing the surface of the middle electrode layer 423, it has an advantageous effect on the formation of the variable resistance layer 424, thereby improving characteristics of the memory cell 420.

In this embodiment, the width W4 of the M-pattern may be greater than the width W3 of the S-pattern. For example, the width of the variable resistance layer 424 disposed at a lower portion of the M-pattern may be greater than the width of the middle electrode layer 423 disposed at an upper portion of the S-pattern. Accordingly, it is possible to prevent the middle electrode layer 423 from being etched during over-etching for separating the M-pattern. Therefore, it is possible to effectively control the occurrence of shunt failure caused by the redeposition of the material included in the middle electrode layer 423 on the sidewalls of the variable resistance layer 424.

In the embodiment shown in FIG. 4, the width W4 of the M-pattern is greater than the width W3 of the S-pattern. In another embodiment, the width W4 of the M-pattern may be the same as the width W3 of the S-pattern. Even in this case, the same effect as that in the embodiment shown in FIG. 4 can be obtained.

The substrate 400, the first conductive line 410, the memory cell 420, the lower electrode layer 421, the selector layer 422, the middle electrode layer 423, the variable resistance layer 424, the upper electrode layer 425, the second conductive line 430, the first capping layer 450, the first gap-fill layer 460, the second capping layer 480 and the second gap-fill layer 490 shown in FIG. 4 may correspond to the substrate 100, the first conductive line 110, the memory cell 120, the lower electrode layer 121, the selector layer 122, the middle electrode layer 123, the variable resistance layer 124, the upper electrode layer 125, the second conductive line 130, the first capping layer 150, the first gap-fill layer 160, the second capping layer 180 and the second gap-fill layer 190 shown in FIG. 1B, respectively.

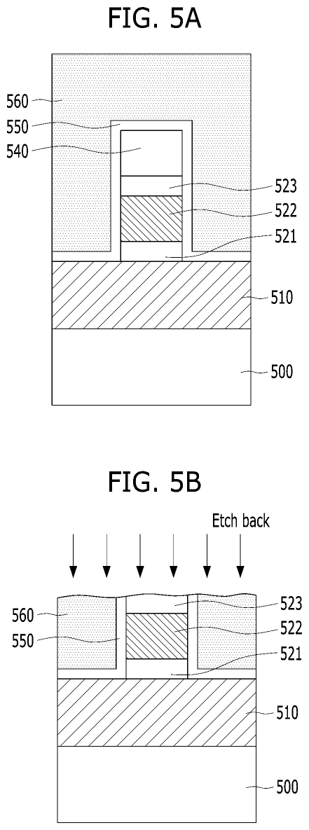

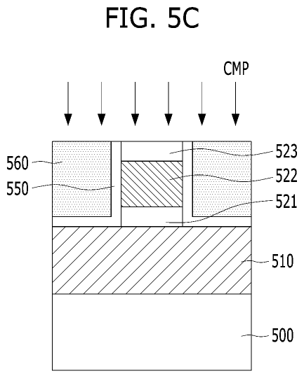

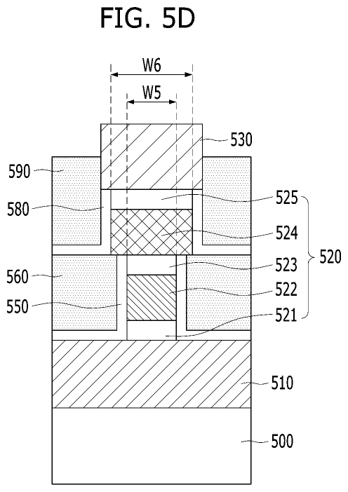

FIGS. 5A to 5D are cross-sectional views illustrating a semiconductor device and a method for forming the same in accordance with an embodiment of the present invention.

The embodiment shown in FIGS. 5A to 5D is similar to the embodiments shown in FIGS. 3A to 3J and FIG. 4 except that an etchback process is further performed before performing the planarization process shown in FIG. 3E. Therefore, detailed description of contents similar to those explained with reference to FIGS. 3A to 3J and FIG. 4 will be omitted.

In the embodiment shown in FIGS. 5A to 5D, an upper pattern disposed at an upper portion of a memory cell 520 is an M-pattern including a variable resistance layer 524 and an upper electrode layer 525 and a lower pattern disposed at a lower portion of the memory cell 520 is an S-pattern including a lower electrode layer 521, a selector layer 522 and a middle electrode layer 523.

Referring to FIG. 5A, by performing processes similar to those described in FIGS. 3A to 3D, a first conductive line 510, the lower electrode layer 521, the selector layer 522, the middle electrode layer 523, a first hard mask pattern 540, a first capping layer 550 and a first gap-fill layer 560 may be formed over a substrate 500.

Referring to FIG. 5B, an etchback process may be performed to remove the first hard mask pattern 540 and expose the middle electrode layer 523.

Referring to FIG. 5C, a planarization process may be performed to form a flat surface of the middle electrode layer 523.

In this embodiment, by performing both the etchback process and the planarization process before forming the M-pattern including the variable resistance layer 524 and the upper electrode layer 525, it is possible to form flat surface morphology of the middle electrode layer 523. Therefore, the crystal growth of the variable resistance layer 524 formed over the middle electrode layer 523 can be improved, thereby efficiently increasing the yield and performance of the variable resistance layer 524.

Referring to FIG. 5D, by performing processes similar to those described in FIGS. 3F to 3J, the semiconductor device including the first conductive line 510, the memory cell 520, the second conductive line 530, the first capping layer 550, the first gap-fill layer 560, a second capping layer 580 and a second gap-fill layer 590 may be formed. The memory cell 520 may include the lower electrode layer 521, the selector layer 522, the middle electrode layer 523, the variable resistance layer 524 and the upper electrode layer 525 which are sequentially stacked. In this embodiment, like the embodiment shown in FIG. 4, the width W6 of the M-pattern including the variable resistance layer 524 and the upper electrode layer 525 is greater than the width W5 of the S-pattern including the lower electrode layer 521, the selector layer 522 and the middle electrode layer 523. In another embodiment, the width W6 of the M-pattern may be the same as the width W5 of the S-pattern.

The substrate 500, the first conductive line 510, the memory cell 520, the lower electrode layer 521, the selector layer 522, the middle electrode layer 523, the variable resistance layer 524, the upper electrode layer 525, the second conductive line 530, the first capping layer 550, the first gap-fill layer 560, the second capping layer 580 and the second gap-fill layer 590 shown in FIG. 5D may correspond to the substrate 400, the first conductive line 410, the memory cell 420, the lower electrode layer 421, the selector layer 422, the middle electrode layer 423, the variable resistance layer 424, the upper electrode layer 425, the second conductive line 430, the first capping layer 450, the first gap-fill layer 460, the second capping layer 480 and the second gap-fill layer 490 shown in FIG. 4 respectively, and the substrate 100, the first conductive line 110, the memory cell 120, the lower electrode layer 121, the selector layer 122, the middle electrode layer 123, the variable resistance layer 124, the upper electrode layer 125, the second conductive line 130, the first capping layer 150, the first gap-fill layer 160, the second capping layer 180 and the second gap-fill layer 190 shown in FIG. 1B, respectively.

In the embodiment shown in FIGS. 5A to 5D, the variable resistance layer 524 is formed over the selector layer 522. In another embodiment, the relative positions of the variable resistance layer 524 and the selector layer 522 may be reversed.

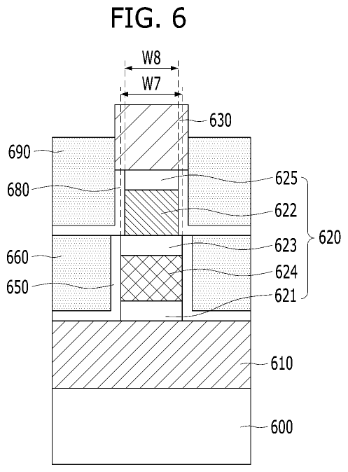

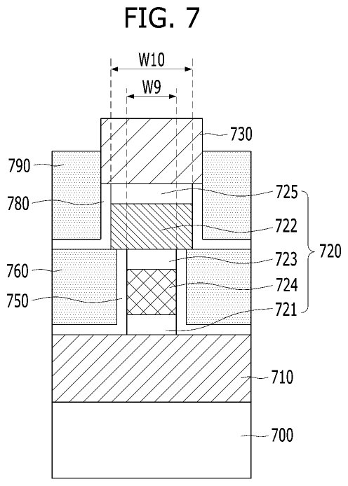

In the embodiments described above, each of the variable resistance layers 124, 324, 424 and 524 is formed at an upper portion of each of the memory cells 120, 320, 420 and 520 and each of the selector layers 122, 322, 422 and 522 is formed at a lower portion of each of the memory cells 120, 320, 420 and 520. In other embodiments, the relative positions of each of the variable resistance layer 124, 324, 424 and 524 and each of the selector layers 122, 322, 422 and 522 may be reversed. This will be described with reference to FIGS. 6 and 7.

FIG. 6 is a cross-sectional view illustrating a semiconductor device in accordance with an embodiment of the present invention.

The embodiment shown in FIG. 6 is similar to the embodiment shown in FIGS. 3A to 3J except that a variable resistance layer 624 is formed under a selector layer 622. Therefore, detailed description of contents similar to those explained with reference to FIGS. 3A to 3J will be omitted.

In the embodiment shown in FIG. 6, an upper pattern disposed at an upper portion of a memory cell 620 is an S-pattern including the selector layer 622 and an upper electrode layer 625 and a lower pattern disposed at a lower portion of the memory cell 620 is an M-pattern including a lower electrode layer 621, a variable resistance layer 624 and a middle electrode layer 623.

Referring to FIG. 6, the semiconductor device may include a substrate 600, a first conductive line 610, a memory cell 620, a second conductive line 630, a first capping layer 650, a first gap-fill layer 660, a second capping layer 680 and a second gap-fill layer 690. The memory cell 620 may include the lower electrode layer 621, the variable resistance layer 624, the middle electrode layer 623, the selector layer 622 and the upper electrode layer 625 which are sequentially stacked.

In this embodiment, the M-pattern including the lower electrode layer 621, the variable resistance layer 624 and the middle electrode layer 623 is formed at a lower portion of the memory cell 620 and the S-pattern including the selector layer 622 and the upper electrode layer 625 is formed at an upper portion of the memory cell 620. According to this embodiment, the M-pattern and the S-pattern may be formed by a separate patterning process. As such, it is possible to reduce an etch burden and increase etch efficiency, thereby allowing for securing a further improved vertical profile and minimizing damage to the sidewalls of the memory cell 620. In this embodiment, the width W8 of the S-pattern is smaller than the width W7 of the M-pattern. In another embodiment, the width W8 of the S-pattern may be the same as or greater than the width W7 of the M-pattern. This will be described with reference to FIG. 7.

FIG. 7 is a cross-sectional view illustrating a semiconductor device in accordance with an embodiment of the present invention.

The embodiment shown in FIG. 7 is similar to the embodiment shown in FIG. 4 except that a variable resistance layer 724 is formed under a selector layer 722. Therefore, detailed description of contents similar to those explained with reference to FIG. 4 will be omitted.

In the embodiment shown in FIG. 7, an upper pattern disposed at an upper portion of a memory cell 720 is an S-pattern including the selector layer 722 and an upper electrode layer 725 and a lower pattern disposed at a lower portion of the memory cell 720 is an M-pattern including a lower electrode layer 721, a variable resistance layer 724 and a middle electrode layer 723.

Referring to FIG. 7, the semiconductor device may include a substrate 700, a first conductive line 710, the memory cell 720, a second conductive line 730, a first capping layer 750, a first gap-fill layer 760, a second capping layer 780 and a second gap-fill layer 790. The memory cell 720 may include the lower electrode layer 721, the variable resistance layer 724, the middle electrode layer 723, the selector layer 722 and the upper electrode layer 725 which are sequentially stacked.

In this embodiment, the M-pattern including the lower electrode layer 721, the variable resistance layer 724 and the middle electrode layer 723 is formed at a lower portion of the memory cell 720 and the S-pattern including the selector layer 722 and the upper electrode layer 725 is formed at an upper portion of the memory cell 720. According to this embodiment, the M-pattern and the S-pattern may be formed by a separate patterning process. As such, it is possible to reduce an etch burden and increase etch efficiency, thereby allowing for securing a further improved vertical profile and minimizing damage to the sidewalls of the memory cell 720.

In this embodiment, the width W10 of the S-pattern is greater than the width W9 of the M-pattern. That is, the width of the selector layer 722 disposed at a lower portion of the S-pattern may be greater than the width of the middle electrode layer 723 disposed at an upper portion of the M-pattern. Accordingly, it is possible to prevent the middle electrode layer 723 from being exposed and etched during over-etching for separating the selector layer 722 and the upper electrode layer 725. Therefore, it is possible to effectively control the occurrence of shunt failure caused by the redeposition of the material included in the middle electrode layer 723 on the sidewalls of the variable resistance layer 724.

In the embodiment shown in FIG. 7, the width W10 of the S-pattern is greater than the width W9 of the M-pattern. In another embodiment, the width W10 of the S-pattern may be the same as the width W9 of the M-pattern. Even in this case, the same effect as that in the embodiment shown in FIG. 7 can be obtained.

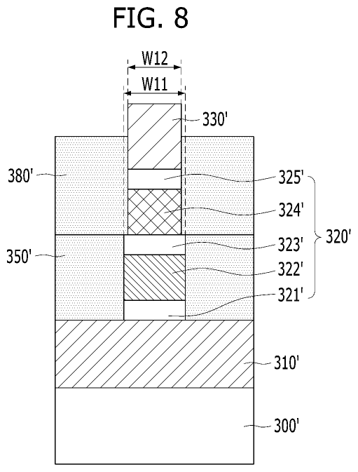

In the embodiments described above, each of the semiconductor devices includes each of the first gap-fill layers 160, 360, 460, 560, 660 and 760 and each of the second gap-fill layers 190, 390, 490, 590, 690 and 790 in addition to each of the first capping layers 150, 350, 450, 550, 650 and 750 and each of the second capping layers 180, 380, 480, 580, 680 and 780. In another embodiment, the gap-fill layer may not be formed and spaces between the memory cells may be filled with further capping layer. In this case, the further capping layer may be referred to as an interlayer capping layer. This will be described with reference to FIGS. 8 to 11.

FIGS. 8 to 11 are cross-sectional views illustrating semiconductor devices in accordance with an embodiment of the present invention.

In the embodiments shown in FIGS. 8 to 11, first interlayer capping layers 350′, 450′, 650′ and 750′ and second interlayer capping layers 380′, 480′, 680′ and 780′ may include an insulating material, or poly-Si, or a combination thereof and may have a single-layered or a multi-layered structure. The insulating material may include an oxide, or a nitride, or a combination thereof. For example, the first interlayer capping layers 350′, 450′, 650′ and 750′ and the second interlayer capping layers 380′, 480′, 680′ and 780′ may include SiO₂, SiN₄, SiOCN, SiON, or poly-Si, or a combination thereof.

The first interlayer capping layers 350′, 450′, 650′ and 750′ and the second interlayer capping layers 380′, 480′, 680′ and 780′ may include the same material as each other or different materials from each other.

Since, in the embodiments shown in FIGS. 8 to 11, spaces between each of memory cells 320′, 420′, 620′ and 720′ may be filled with each of the first interlayer capping layers 350′, 450′, 650′ and 750′ and each of the second interlayer capping layers 380′, 480′, 680′ and 780′ without further gap-fill layers filling the spaces. The first interlayer capping layers 350′, 450′, 650′ and 750′ and the second interlayer capping layers 380′, 480′, 680′ and 780′ may be formed to effectively prevent interference between each of the memory cells 320′, 420′, 620′ and 720′.

For example, the first interlayer capping layers 350′, 450′, 650′ and 750′ and the second interlayer capping layers 380′, 480′, 680′ and 780′ may include an air space formed in a void shape. Since the void has a low permittivity, interference between each of the memory cells 320′, 420′, 620′ and 720′ can be effectively prevented by each of the first interlayer capping layers 350′, 450′, 650′ and 750′ and each of the second interlayer capping layers 380′, 480′, 680′ and 780′. The air space in a void shape may be formed by increasing the deposition rate, for example, by increasing temperature, pressure, power or gas flow rate.

The embodiment shown in FIG. 8 is similar to the embodiment shown in FIGS. 3A to 3J except that the first gap-fill layer 360 and the second gap-fill layer 390 are not formed and spaces between the memory cells 320′ are filled with the first interlayer capping layer 350′ and the second interlayer capping layer 380′. Therefore, detailed description of contents similar to those explained with reference to FIGS. 3A to 3J will be omitted.

In the embodiment shown in FIG. 8, an upper pattern disposed at an upper portion of the memory cell 320′ is an M-pattern including a variable resistance layer 324′ and an upper electrode layer 325′ and a lower pattern disposed at a lower portion of the memory cell 320′ is an S-pattern including a lower electrode layer 321′, a selector layer 322′ and a middle electrode layer 323′.

Referring to FIG. 8, the semiconductor device may include a substrate 300′, a first conductive line 310′, the memory cell 320′, a second conductive line 330′, the first interlayer capping layer 350′ and the second interlayer capping layer 380′. The memory cell 320′ may include the lower electrode layer 321′, the selector layer 322′, the middle electrode layer 323′, the variable resistance layer 324′ and the upper electrode layer 325′ which are sequentially stacked.

The first interlayer capping layer 350′ and the second interlayer capping layer 380′ may be formed to entirely fill spaces between the memory cells 320′. The first interlayer capping layer 350′ may be formed to surround sidewalls of the S-pattern including the lower electrode layer 321′, the selector layer 322′ and the middle electrode layer 323′. The second interlayer capping layer 380′ may be formed to surround sidewalls of the M-pattern including the variable resistance layer 324′ and the upper electrode layer 325′.

In an embodiment, the first interlayer capping layer 350′ and the second interlayer capping layer 380′ may include an air space formed in a void shape and have a low permittivity, thereby effectively preventing interference between the memory cells 320′.

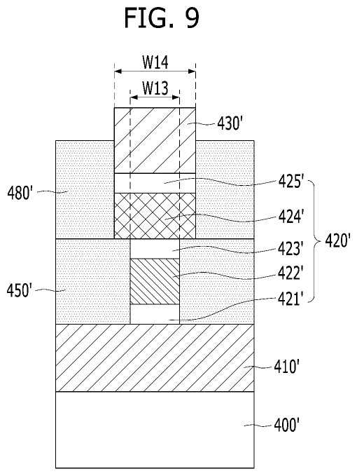

In this embodiment, the width W12 of the M-pattern is smaller than the width W11 of the S-pattern. In another embodiment, the width W12 of the M-pattern is the same as or greater than width W11 of the S-pattern. This will be described with reference to FIG. 9.

The embodiment shown in FIG. 9 is similar to the embodiment shown in FIG. 4 except that the first gap-fill layer 460 and the second gap-fill layer 490 are not formed and spaces between the memory cells 420′ are filled with the first interlayer capping layer 450′ and the second interlayer capping layer 480′. Detailed description of contents similar to those explained with reference to FIG. 4 will be omitted.

Referring to FIG. 9, the semiconductor device may include a substrate 400′, a first conductive line 410′, the memory cell 420′, a second conductive line 430′, the first interlayer capping layer 450′ and the second interlayer capping layer 480′. The memory cell 420′ may include a lower electrode layer 421′, a selector layer 422′, a middle electrode layer 423′, a variable resistance layer 424′ and an upper electrode layer 425′ which are sequentially stacked. In this embodiment, the width of the M-pattern including the variable resistance layer 424′ and the upper electrode layer 425′ may be the same as or greater than the width of the S-pattern including the lower electrode layer 421′, the selector layer 422′ and the middle electrode layer 423′.

The first interlayer capping layer 450′ and the second interlayer capping layer 480′ may be formed to entirely fill spaces between the memory cells 420′. The first interlayer capping layer 450′ may be formed to surround sidewalls of the S-pattern including the lower electrode layer 421′, the selector layer 422′ and the middle electrode layer 423′. The second interlayer capping layer 480′ may be formed to surround sidewalls of the M-pattern including the variable resistance layer 424′ and the upper electrode layer 425′.

In an embodiment, the first interlayer capping layer 450′ and the second interlayer capping layer 480′ may include an air space formed in a void shape and have a low permittivity, thereby effectively preventing interference between the memory cells 420′.

In this embodiment, the width W14 of the M-pattern may be greater than the width W13 of the S-pattern. Accordingly, it is possible to prevent the middle electrode layer 423′ from being etched during over-etching for separating the M-pattern. Therefore, it is possible to effectively control the occurrence of shunt failure caused by the redeposition of the material included in the middle electrode layer 423′ on the sidewalls of the variable resistance layer 424′.

In the embodiment shown in FIG. 9, the width W14 of the M-pattern is greater than the width W13 of the S-pattern. In another embodiment, the width W14 of the M-pattern is the same as the width W13 of the S-pattern. Even in this case, the same effect as that in the embodiment shown in FIG. 9 can be obtained.

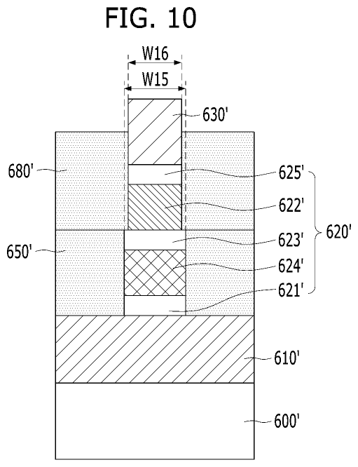

The embodiment shown in FIG. 10 is similar to the embodiment shown in FIG. 6 except that the first gap-fill layer 660 and the second gap-fill layer 690 are not formed and spaces between the memory cells 620′ are filled with the first interlayer capping layer 650′ and the second interlayer capping layer 680′. Therefore, detailed description of contents similar to those explained with reference to FIG. 6 will be omitted.

In the embodiment shown in FIG. 10, an upper pattern disposed at an upper portion of the memory cell 620′ is an S-pattern including a selector layer 622′ and an upper electrode layer 625′ and a lower pattern disposed at a lower portion of the memory cell 620′ is an M-pattern including a lower electrode layer 621′, a variable resistance layer 624′ and a middle electrode layer 623′.

Referring to FIG. 10, the semiconductor device may include a substrate 600′, a first conductive line 610′, the memory cell 620′, a second conductive line 630′, the first interlayer capping layer 650′ and the second interlayer capping layer 680′. The memory cell 620′ may include the lower electrode layer 621′, the variable resistance layer 624′, the middle electrode layer 623′, the selector layer 622′ and the upper electrode layer 625′ which are sequentially stacked.

The first interlayer capping layer 650′ and the second interlayer capping layer 680′ may be formed to entirely fill spaces between the memory cells 620′. The first interlayer capping layer 650′ may be formed to surround sidewalls of the M-pattern including the lower electrode layer 621′, the variable resistance layer 624′ and the middle electrode layer 623′. The second interlayer capping layer 680′ may be formed to surround sidewalls of the S-pattern including the selector layer 622′ and the upper electrode layer 325′.

In an embodiment, the first interlayer capping layer 650′ and the second interlayer capping layer 680′ may include an air space formed in a void shape and have a low permittivity, thereby effectively preventing interference between the memory cells 620′.

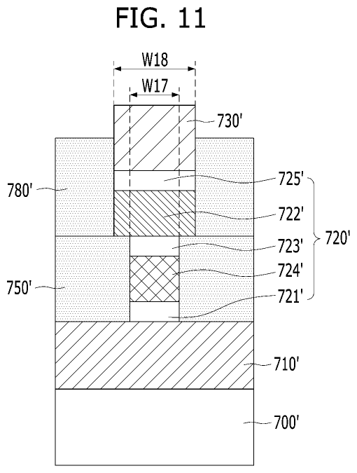

In this embodiment, the width W16 of the S-pattern is smaller than the width W15 of the M-pattern. In another embodiment, the width W16 of the S-pattern may be the same as or greater than the width W15 of the M-pattern. This will be described with reference to FIG. 11.

The embodiment shown in FIG. 11 is similar to the embodiment shown in FIG. 7 except that the first gap-fill layer 760 and the second gap-fill layer 790 are not formed and spaces between the memory cells 720′ are filled with the first interlayer capping layer 750′ and the second interlayer capping layer 780′. Therefore, detailed description of contents similar to those explained with reference to FIG. 7 will be omitted.

Referring to FIG. 11, the semiconductor device may include a substrate 700′, a first conductive line 710′, the memory cell 720′, a second conductive line 730′, the first interlayer capping layer 750′ and the second interlayer capping layer 780′. The memory cell 720′ may include a lower electrode layer 721′, a variable resistance layer 724′, a middle electrode layer 723′, a selector layer 722′ and an upper electrode layer 725′ which are sequentially stacked. In this embodiment, the width of the M-pattern including the lower electrode layer 721′, variable resistance layer 724′ and the middle electrode layer 723′ may be the same as or greater than the width of the S-pattern including the selector layer 722′ and the upper electrode layer 725′.

The first interlayer capping layer 750′ and the second interlayer capping layer 780′ may be formed to entirely fill spaces between the memory cells 720′. The first interlayer capping layer 750′ may be formed to surround sidewalls of the M-pattern including the lower electrode layer 721′, the variable resistance layer 724′ and the middle electrode layer 723′. The second interlayer capping layer 780′ may be formed to surround sidewalls of the S-pattern including the selector layer 722′ and the upper electrode layer 725′.

In an embodiment, the first interlayer capping layer 750′ and the second interlayer capping layer 780′ may include an air space formed in a void shape and have a low permittivity, thereby effectively preventing interference between the memory cells 720′.

In this embodiment, the width W18 of the S-pattern may be greater than the width W17 of the M-pattern. For example, the width of the selector layer 722′ disposed at a lower portion of the S-pattern may be greater than the width of the middle electrode layer 723′ disposed at an upper portion of the M-pattern. Accordingly, it is possible to prevent the middle electrode layer 723′ from being etched during over-etching for separating the S-pattern. Therefore, it is possible to effectively control the occurrence of shunt failure caused by the redeposition of the material included in the middle electrode layer 723′ on the sidewalls of the variable resistance layer 724′.

In the embodiment shown in FIG. 11, the width W18 of the S-pattern is greater than the width W17 of the M-pattern. In another embodiment, the width W18 of the S-pattern may be the same as the width W17 of the M-pattern. Even in this case, the same effect as that in the embodiment shown in FIG. 11 can be obtained.

While the present invention has been described with respect to specific embodiments, it should be noted that the embodiments are for describing, not limiting, the present invention. Further, it should be noted that the present invention may be achieved in various ways through substitution, change, and modification, by those skilled in the art without departing from the scope of the present invention as set forth in the descriptions above.

What is claimed is:

1. A semiconductor device comprising:
a first pattern including any one of a selector layer or a variable resistance layer and a middle electrode layer disposed over any one of the selector layer or the variable resistance layer; and
a second pattern disposed over the first pattern and including the other one of the selector layer or the variable resistance layer,
wherein a width of the second pattern is the same as or greater than a width of the first pattern.

2. The semiconductor device of claim 1, further comprising:
a first capping layer disposed on sidewalls of the first pattern; and
a second capping layer disposed on sidewalls of the second pattern.

3. The semiconductor device of claim 2, further comprising:
a first gap-fill layer filling spaces between the first patterns; and
a second gap-fill layer filling spaces between the second patterns.

4. The semiconductor device of claim 2, wherein the first capping layer and the second capping layer have a single-layered structure or a multi-layered structure including an insulating material, or poly-Si, or a combination thereof.

5. The semiconductor device of claim 3, wherein the first capping layer and the first gap-fill layer include the same material.

6. The semiconductor device of claim 1, further comprising:
a first interlayer capping layer filling spaces between the first patterns; and
a second interlayer capping layer filling spaces between the second patterns.

7. The semiconductor device of claim 6, wherein the first interlayer capping layer and the second interlayer capping layer have a single-layered structure or a multi-layered structure including an insulating material, or poly-Si, or a combination thereof.

8. The semiconductor device of claim 6, wherein the first interlayer capping layer and the second interlayer capping layer include an air space formed in a void shape.

9. The semiconductor device of claim 1, wherein the first pattern further includes a lower electrode layer disposed under any one of the selector layer or the variable resistance layer.

10. The semiconductor device of claim 1, wherein the second pattern further includes an upper electrode layer disposed over the other one of the selector layer or the variable resistance layer.

11. The semiconductor device of claim 1, wherein the middle electrode layer has planarized surface morphology.

12. The semiconductor device of claim 1, wherein the variable resistance layer includes any one of a variable resistance material, a phase change material, a ferroelectric material or a ferromagnetic material.

13. A method for fabricating a semiconductor device comprising:
forming a first material layer for forming any one of a selector layer or a variable resistance layer over a substrate;
forming a second material layer for forming a middle electrode layer over the first material layer;
etching the second material layer and the first material layer through a first patterning process using a first hard mask pattern to form a first pattern including any one of the selector layer or the variable resistance layer and the middle electrode layer;
forming a third material layer for forming the other one of the selector layer or the variable resistance layer over the first pattern; and
etching the third material layer through a second patterning process using a second hard mask pattern to form a second pattern including the other one of the selector layer or the variable resistance layer.

14. The method of claim 13, further comprising, after the forming of the first pattern,
performing a planarization process to expose and planarize a surface of the middle electrode layer.

15. The method of claim 13, further comprising, after the forming of the first pattern,
performing an etchback process and a subsequent planarization process to expose and planarize a surface of the middle electrode layer.

16. The method of claim 13, further comprising, after the forming of the first pattern,
forming a first capping layer disposed on sidewalls of the first pattern; and
forming a first gap-fill layer filling spaces between the first patterns.

17. The method of claim 16, wherein the first capping layer, the first gap-fill layer and the first hard mask pattern are formed by the same material as each other.

18. The method of claim 13, further comprising, after the forming of the first pattern,
forming a first interlayer capping layer filling spaces between the first patterns.

19. The method of claim 18, wherein the forming of the first interlayer capping layer is performed such that the first interlayer capping layer includes an air space in a void shape by adjusting deposition conditions.

20. The method of claim 18, wherein the first interlayer capping layer and the first hard mask pattern are formed by the same material as each other.

21. The method of claim 13, wherein a surface of the middle electrode layer is not exposed during the etching of the third material layer.

22. The method of claim 13, further comprising, after the forming of the second pattern,
forming a second capping layer disposed on sidewalls of the second pattern; and
forming a second gap-fill layer filling spaces between the second patterns.

23. The method of claim 13, further comprising, after the forming of the second pattern,
forming a second interlayer capping layer filling spaces between the second patterns.

24. The method of claim 23, wherein the forming of the second interlayer capping layer is performed such that the second interlayer capping layer includes an air space in a void shape by adjusting deposition conditions.

25. A method for fabricating a semiconductor device comprising:
forming a first pattern including any one of a selector layer or a variable resistance layer and a middle electrode layer disposed over any one of the selector layer or the variable resistance layer over a substrate; and
forming a second pattern including the other one of the selector layer or the variable resistance layer over the first pattern,
wherein a width of the second pattern is the same as or greater than a width of the first pattern.

26. The method according to claim 25, wherein the forming of the first pattern includes:
forming a first material layer for forming any one of the selector layer or the variable resistance layer over the substrate;
forming a second material layer for forming the middle electrode layer over the first material layer;
forming a first hard mask pattern over the second material layer; and
etching the second material layer and the first material layer by using the first hard mask pattern to form a structure in which any one of the selector layer or the variable resistance layer, the middle electrode layer and the first hard mask pattern are sequentially stacked.

27. The method according to claim 25, further comprising, after the forming of the first pattern,
performing a planarization process to expose and planarize a surface of the middle electrode layer.

28. The method according to claim 25, further comprising, after the forming of the first pattern,
performing an etchback process and a subsequent planarization process to expose and planarize a surface of the middle electrode layer.

29. The method according to claim 25, further comprising, after the forming of the first pattern,
conformally forming a first capping layer over the first pattern; and
forming a first gap-fill layer to cover the first capping layer and fill spaces between the first patterns.

30. The method according to claim 29, wherein the first capping layer, the first gap-fill layer and the first hard mask pattern are formed by the same material.

31. The method according to claim 25, further comprising, after the forming of the first pattern,
forming a first interlayer capping layer to cover the first pattern and fill spaces between the first patterns.

32. The method according to claim 31, wherein the forming of the first interlayer capping layer is performed such that the first interlayer capping layer includes an air space in a void shape by adjusting deposition conditions.

33. The method according to claim 31, wherein the first interlayer capping layer and the first hard mask pattern are formed by the same material.

34. The method according to claim 25, wherein the forming of the second pattern includes,
forming a third material layer for forming the other one of the selector layer or the variable resistance layer over the first pattern;
forming a second hard mask pattern over the third material layer; and
etching the third material layer by using the second hard mask pattern to form the other one of the selector layer or the variable resistance layer over the middle electrode layer.

35. The method according to claim 34, wherein a surface of the middle electrode layer is not exposed during the etching of the third material layer.

36. The method according to claim 25, further comprising, after the forming of the second pattern,
forming a second capping layer disposed on sidewalls of the second pattern; and
forming a second gap-fill layer filling spaces between the second patterns.

37. The method according to claim 25, further comprising, after the forming of the second pattern,
forming a second interlayer capping layer filling spaces between the second patterns.

38. The method according to claim 37, wherein the forming of the second interlayer capping layer is performed such that the second interlayer capping layer includes an air space in a void shape by adjusting deposition conditions.
